(19) United States
(12) Patent Application Publication
(10) Pub. No.: US 2010/0066568 A1
(43) Pub. Date: Mar. 18, 2010

(54) KEYBOARD STRUCTURE WITH A SELF-LUMINOUS CIRCUIT BOARD

(75) Inventor: Ching-Ping Lee, Panchiao City (TW)

Correspondence Address: Ching-Ping Lee, P.O. BOX 108-00403, Taipei, 106, TW

(73) Assignee: Ching-Ping Lee, Panchiao City (TW)

(21) Appl. No.: 12/238,457

(22) Filed: Sep. 26, 2008

(30) Foreign Application Priority Data
Apr. 18, 2008 (TW) 097114291

(51) Int. Cl. H03M 11/00

(52) U.S. Cl. 341/22

(57) ABSTRACT

A keyboard structure includes a circuit board prepared from a flexible light guide material and carrying a circuit layout, multiple key switch modules for operation by a user to cause the circuit board to produce a respective electrical signal, and multiple luminous units installed in a flexible light guide substrate of the circuit board and electrically connected with the circuit layout for emitting light to illuminate press heads of the key switch modules.

This application claims the priority benefit of Taiwan patent application number 097114291 filed on Apr. 18, 2008.

### BACKGROUND OF THE INVENTION

1. Field of the Invention

The present invention relates to a keyboard structure and more particularly, to a keyboard structure with a self-luminous circuit board, which uses a flexible light guide material for the substrate of the circuit board and installs luminous units in the circuit board for emitting light to illuminate the press head (key cap) of the key switch modules being mounted on the circuit board.

2. Description of the Related Art

Following the development step of modern technology, many advanced electronic products are created to bring convenience to people. Most electronic products use a keyboard, mouse, joystick or light gun for character, number or instruction input. These input devices commonly have key switches for operation by a user to input characters, numbers or instructions. Further, following the development of advanced electronic products toward light, thin, short and small characteristics, the features of a keyboard structure for electronic product must be relatively changed. For example, a keyboard structure for a conventional desktop computer is not suitable for a notebook computer. For use in a notebook computer, the basic design of a keyboard structure for desktop computer must be relatively modified.

Further, the keyboard structure of an old design of mobile phone does not emit light for illumination. When using an old design of mobile phone in the dark, the user cannot accurately press the operation buttons. To solve this problem, keyboard illumination designs are created. FIG. 10 illustrates a key switch illumination system according to the prior art. According to this design, the key switch illumination system comprises a key switch unit A, and a backlight device B. The key switch unit A comprises a frame A1, a circuit board A2 arranged on the top side of the frame A1 and carrying a light emitting device A21 that is controllable to emit light toward the frame A1 and the backlight device B, a rubber membrane A3 arranged on the top side of the circuit board A2 and carrying a rubber cone A31, a key cap A5 suspending above the rubber membrane A3, and a linking device A4 coupled between the key cap A5 and the frame A1. The backlight device B comprises a light guide board B1 provided at the bottom side of the frame B1, and a reflector B2 provided at the bottom side of the light guide board B1. During operation, the light emitting device A21 emits light downwardly through (a hole on) the frame A1 and the light guide board B1, and the reflector B2 reflects the light upwards toward the key switch unit A to illuminate the key cap A5. According to this key switch illumination system, the key switch unit A and the backlight device B use a big number of component parts, complicating the fabrication and increasing the manufacturing cost. Further, a keyboard structure based on this key switch illumination system has a certain thickness, not in conformity with the requirements for a low profile design.

### SUMMARY OF THE INVENTION

The present invention has been accomplished under the circumstances in view. It is therefore the main object of the present invention to provide a keyboard structure with a self-luminous circuit board, which is easy and inexpensive to manufacture, and satisfies the requirements for a low profile design.

To achieve this and other objects of the present invention, the keyboard structure comprises a circuit board and a plurality of key switch modules installed in the circuit board. The circuit board is prepared from a flexible light guide material and carrying a circuit layout and set beneath a frame of each key switch module or between a frame and a press head of each key switch module, having at least one luminous unit mounted therein for emitting light upwardly to illuminate the press heads of the key switch modules. Because the circuit board has a circuit layout controllable by the key switch modules to produce electrical signals and works as a light guide board, the dual-function circuit board design reduces the number of component parts required for the keyboard structure, simplifying the manufacturing process of the keyboard structure and lowering the manufacturing cost of the keyboard structure. Further, because the keyboard structure does not require any extra light guide board or reflector means, the vertical height of the keyboard structure can be minimized.

### BRIEF DESCRIPTION OF THE DRAWINGS

FIG. 1 is an exploded view of a part of a keyboard structure according to the present invention.

FIG. 2 is a sectional side view in an enlarged scale of FIG. 1.

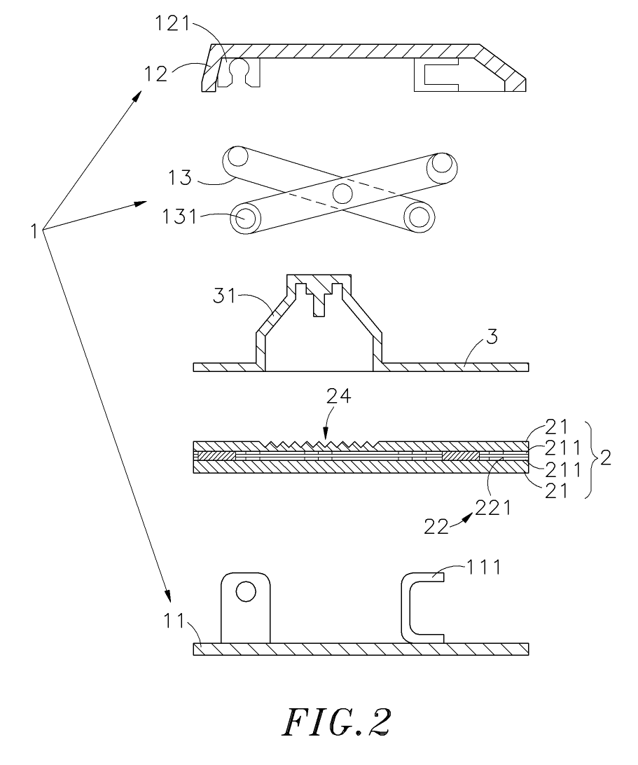

FIG. 3 is a sectional assembly view in an enlarged scale of the keyboard structure shown in FIG. 1.

FIG. 4 is an oblique elevation of a membrane of the keyboard structure shown in FIG. 1.

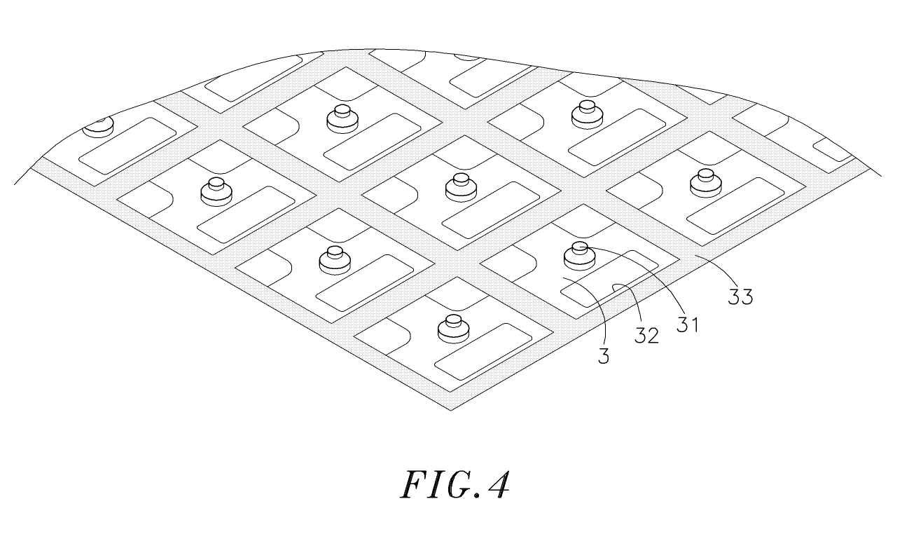

FIG. 5 corresponds to FIG. 1, showing an alternate form of the keyboard structure according to the present invention.

FIG. 6 is a sectional assembly view in an enlarged scale of the keyboard structure shown in FIG. 5, showing the keyboard structure installed in a bottom shell.

FIG. 7 is a schematic drawing showing one installation example of the luminous units of the circuit board of the keyboard structure according to the present invention.

FIG. 8 is a schematic drawing showing another installation example of the luminous units of the circuit board of the keyboard structure according to the present invention.

FIG. 9 is a sectional assembly view in an enlarged scale of another alternate form of the keyboard structure according to the present invention.

FIG. 10 is an exploded view of a part of a keyboard structure according to the prior art.

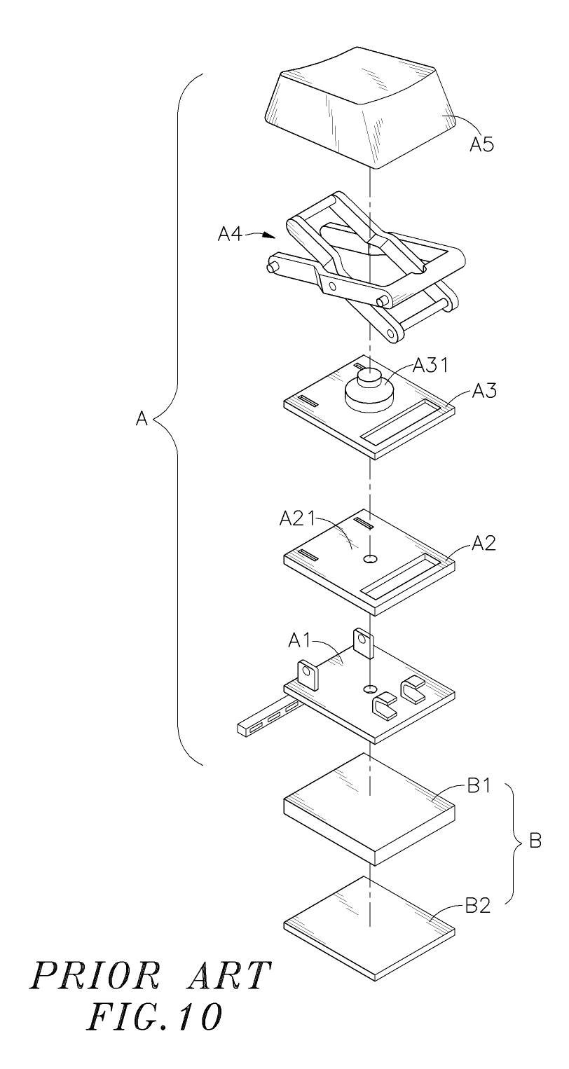

### DETAILED DESCRIPTION OF THE PREFERRED EMBODIMENT

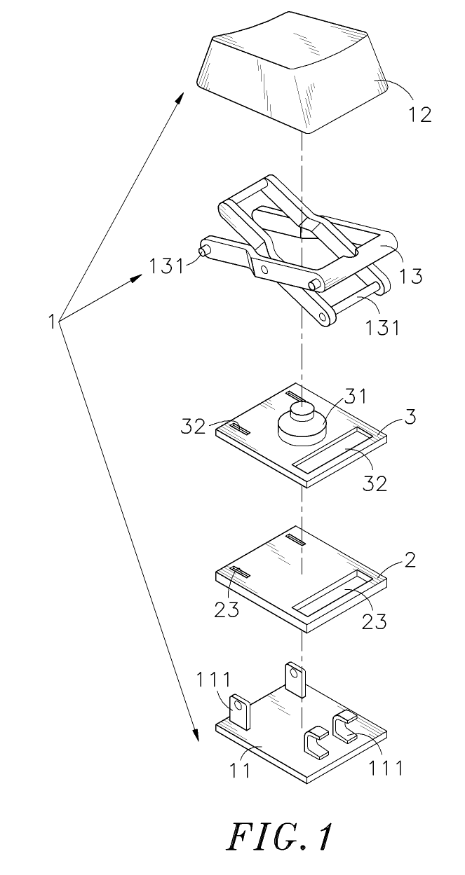

Referring to FIGS. 1˜4, a keyboard structure in accordance with one embodiment of the present invention is shown comprised of a plurality of key switch modules 1, a circuit board 2 and a membrane 3.

Each key switch module 1 comprises a frame 11, which has a plurality of connection portions 111, a press head 12 (for example, a key cap or thin metal sheet), which suspends above the frame 11 and has a plurality of connection portions 121 bilaterally disposed at a bottom side thereof, and a linking device 13, which has coupling portions 131 respectively pivotally coupled to the connection portions 111 of the frame 11 and the connection portions 121 of the press head 12 and is movable in reversed directions to lift or lower the press head 12.

The circuit board 2 comprises two substrates 21 respectively prepared from a light guide material, such as polycarbonate (PC), polyethylene terephthalate (PET) or polymethyl methacrylate (PMMA), a circuit layout 211 arranged in each substrate 21 at the top or bottom side, a plurality of luminous units 22 formed of at least one light emitting device 221 and mounted in between the two substrates 21 corresponding to the key switch modules 1 and electrically connected to the circuit layouts 211, and multiple sets of slots 23 cut through the top and bottom sides thereof corresponding to the key switch modules 1.

The membrane 3 comprises a plurality of compressible rubber cones 31 corresponding to the key switch modules 1, multiple sets of slots 32 cut through the top and bottom sides thereof corresponding to the multiple sets of slots 23 of the circuit board 2. Further, the membrane 3 has a shielding portion 33 disposed around each key switch module 1. The membrane 3 admits light. However, the shielding portion 33 does not admit light.

During the assembly process of the keyboard structure, the membrane 3 is stacked on the circuit board 2 and attached with the circuit board 2 to the top side of the frame 11 of each key switch module 1 to have the connection portions 111 of the frame 11 of each key switch module 1 be respectively inserted through the slots 23 of the circuit board 2 and the slots 32 of the membrane 3, and then the coupling portions 131 of the linking devices 13 of the key switch modules 1 are respectively pivotally coupled to the connection portions 111 of the respective frames 11 and the connection portions 121 of the respective press heads 12.

When a user pressed the press head 12 of one key switch module 1 during the use of the keyboard structure, the linking device 13 of the respective key switch module 1 is lowered for enabling the press head 12 to compress the associating rubber cone 31, causing the circuit board 2 to be driven by the rubber cone 31 to produce a corresponding switch signal. When the user released the pressure from the press head 12, the associating rubber cone 31 immediately returns to its former shape, thereby returning the linking device 13 and the press head 12 of the associating key switch module 1 to their former position.

Further, the aforesaid linking devices 13 can be a scissor action linkage, rotary shaft type linkage, sliding groove type linkage or any other design that enables the press head 12 to be moved vertically with the associating rubber cone 31. Alternatively, the linking device 13 can be eliminated and, the press head 12 can be directly attached to the associating rubber cone 31 and moved with the associating rubber cone 31 upwards/downwards.

Further, the membrane 3 is provided at the top side of the circuit board 2, the press head 12 of each key switch module 1 is suspending above the membrane 3, and the shielding portion 33 of the membrane 3 is disposed around each key switch module 1. Because the membrane 3 admits light and the shielding portion 33 of the membrane 3 does not admit light, light from the light emitting device 221 of each luminous unit 22 of the circuit board 2 goes through the membrane 3 to illuminate the press head 12 of the associating key switch module 1, and the shielding portion 33 prohibits scattering of the light. The shielding portion 33 can be provided with light reflecting means to reflect the light from the light emitting device 221 of each luminous unit 22 of the circuit board 2 toward the press head 12 of the associating key switch module 1.

Further, the circuit board 2 can be made having light guide means 24 in the top side of the top substrate 21 to guide the light from the light emitting device 221 of one luminous unit 22 toward the press head 12 of the associating key switch module 1. The light guide means 24 can be a V-shaped protrusion, V-cut, light guide ink or any of a variety of other designs capable of guiding light from each luminous unit 22 toward the press head 12 of the associating key switch module 1.

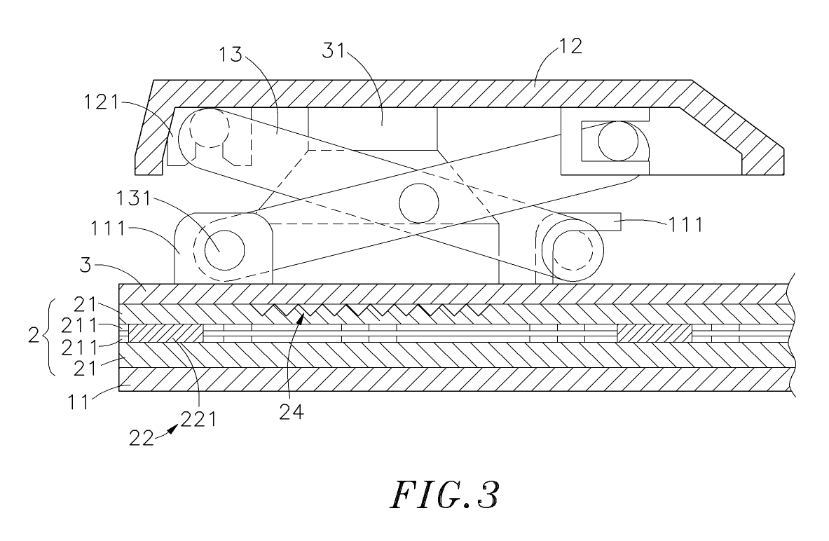

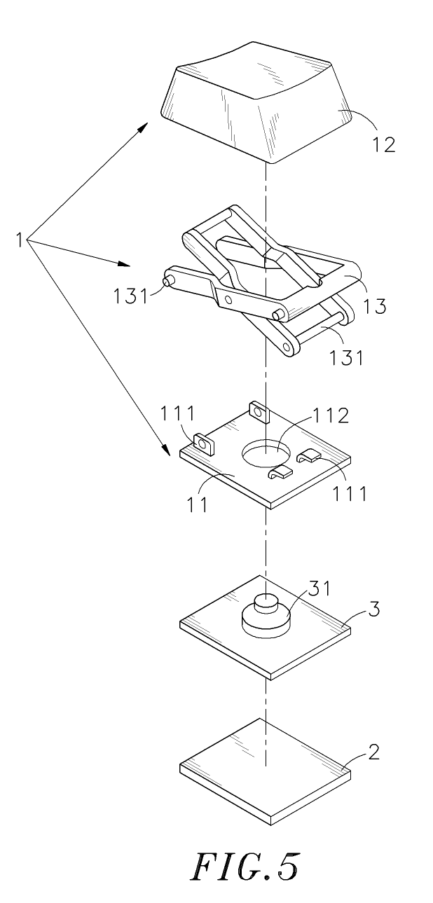

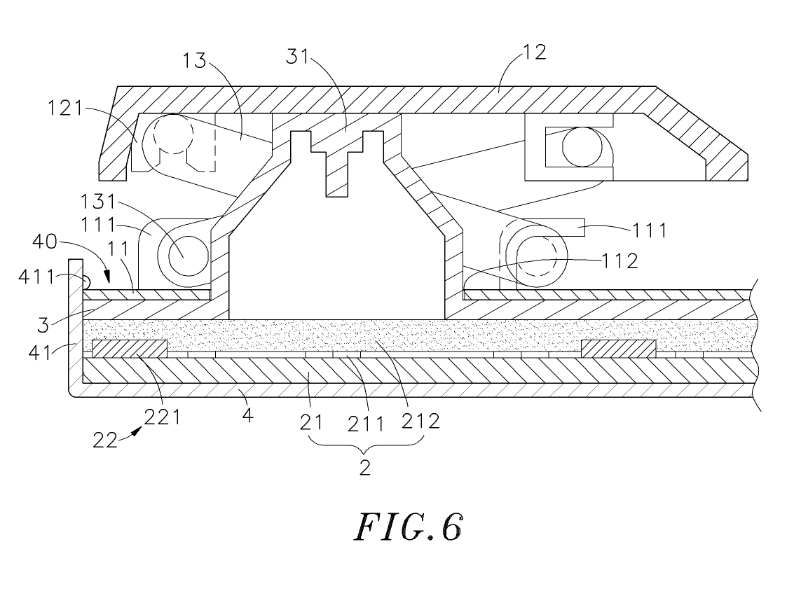

Referring to FIGS. 5 and 6 and FIGS. 1 and 3 again, the circuit board 2 can be a single-layer circuit board comprising one single substrate 21 (see FIG. 6), or a two-layer circuit board comprising two substrates 21 arranged in a stack (as shown in FIG. 3). Further, the frames 11 of the key switch modules 1 can be set beneath the circuit board 2 (see FIGS. 1˜3). Alternatively, the frames 11 of the key switch modules 1 can be set at the top side of the membrane 3 (see FIGS. 5 and 6). Further, a bottom shell 4 is provided to accommodate the keyboard structure (see FIG. 6). As illustrated, the bottom shell 4 has an upright peripheral wall 41 that defines an accommodation chamber 40 that accommodates the keyboard structure, and positioning portions 411 protruded from the inner side of the upright peripheral wall 41 and stopped the top side of the frames 11 of the key switch modules 1 of the keyboard structure to hold down the keyboard structure firmly in the accommodation chamber 40. Actually, the frames 11 of the key switch modules 1 of the keyboard structure are formed in integrity, i.e., the keyboard structure has one single-piece frame that is divided into multiple zones for the key switch modules 1. Further, according to the embodiment shown in FIGS. 5 and 6, the circuit board 2 is a single-layer circuit board comprising one single substrate 21, a circuit layout 211 and multiple luminous units 22 arranged on the substrate 21, and a resin layer 212 covered on the top side of the substrate 21 to protect the circuit layout 211 and the light emitting devices 221 of the luminous units 22 against impact damage or oxidation. Further, according to the embodiment shown in FIGS. 5 and 6, the frame 11 of each key switch module 1 has a center opening 112 for the passing of the associating rubber cone 31 of the membrane 3. Further, the press head 12 can be coated with a layer of paint and then marked with a luminous letter and/or symbol and/or design by means of a laser engraving technique.

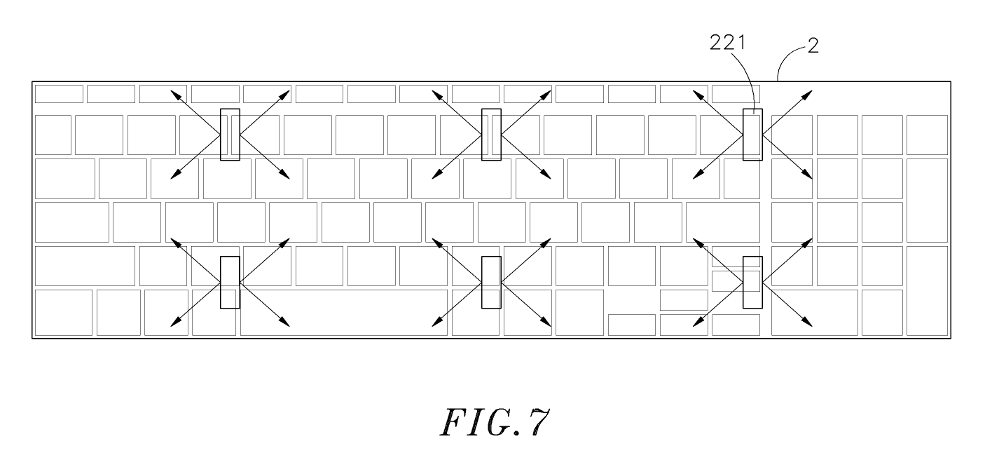

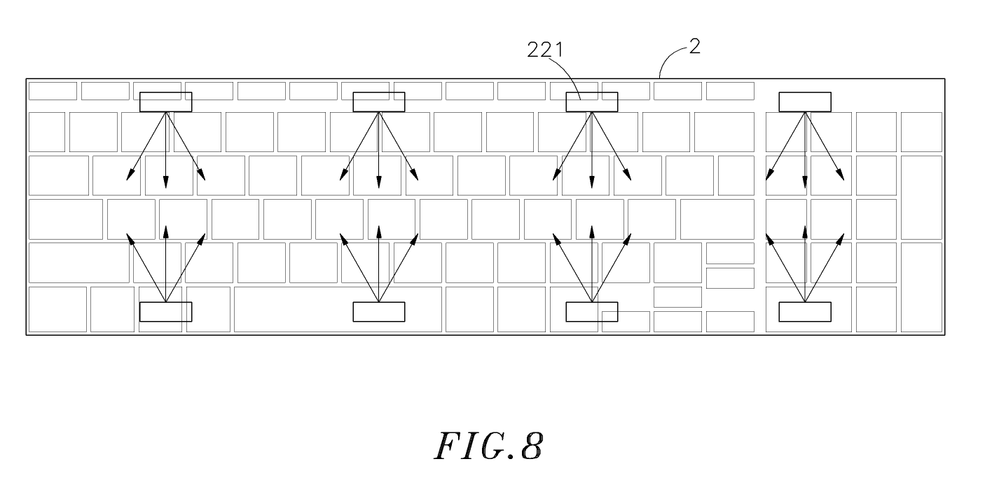

Referring to FIGS. 7 and 8 and FIG. 1 again, the light emitting devices 221 of the luminous units 22 can be arranged at two sides relative to each key switch module 1 (see FIG. 7), or at one side relative to each key switch module 1 (see FIG. 8). That is to say, the light emitting devices 221 of the luminous units 22 can be arranged in the circuit board 2 at any desired locations in any desired directions to emit light toward the press heads 21 of the key switch modules 1 for illumination.

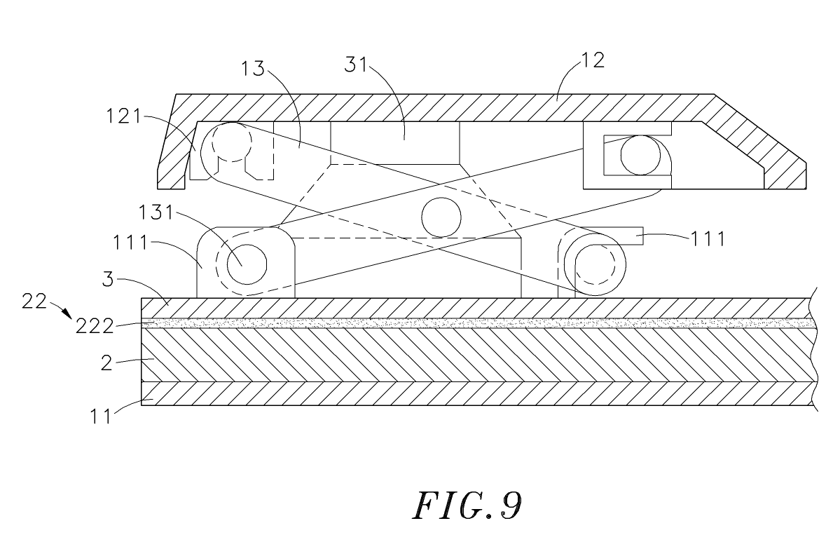

Referring to FIG. 9 and FIG. 1 again, the luminous unit 22 can be an electro luminescent (EL) layer 222 having a light-emitting organic material that emits light when electrically connected. Further, the slots 23 of the circuit board 2 also cut through the electro luminescent (EL) layer 222 for the passing of the connection portions 111 of the key switch modules 1. Because the electro luminescent (EL) layer 222 can be designed to emit light at any location, the formation of the slots 23 does not interfere with the functioning of the luminous units 22. Therefore, the luminous units 22 can effectively illuminate the press heads 12 of the key switch modules 1.

Further, the aforesaid electro luminescent (EL) layer 222 can be formed on the surface of the circuit board 2 by means of screen printing technique. Further, a layer of PET (polyethylene terephthalate) can be covered on the electro luminescent (EL) layer 222 for protection. As the processing process of the electro luminescent (EL) layer 222 is of the known art and not within the scope of the claims of the present invention, not further detailed description in this regard is necessary.

In general, the keyboard structure with a self-luminous circuit board in accordance with the present invention has the features and advantages as below:

1. The keyboard structure comprises multiple key switch modules 1, a circuit board 2 and a membrane 3, wherein the circuit board 2 is prepared from a flexible light guide material and carrying a circuit layout 211 and set beneath the frame 11 of each key switch module 1 or between the frame 11 and the press head 12 of each key switch module 1; the circuit board 2 comprises at least one luminous unit 22 that emits light to illuminate the press heads 12 of the key switch modules 1 when electrically connected. Because the circuit board 2 has a circuit layout 211 and works as a light guide board, the use of the dual-function circuit board design reduces the number of component parts (such as light guide board or reflector board) required for the keyboard structure, simplifying the manufacturing process of the keyboard structure and lowering the manufacturing cost of the keyboard structure.

2. The circuit board 2 is prepared from a flexible light guide material and carrying a circuit layout 211 and set beneath the frame 11 of each key switch module 1 or between the frame 11 and the press head 12 of each key switch module 1, having at least one luminous unit 22 for emitting light to illuminate the press heads 12 of the key switch modules 1. Further, the membrane 3 has a shielding portion 33 disposed around each key switch module 1 to prohibit scattering of the light from each luminous unit 22. This structural design does not require any extra light guide board, reflector board or light shield means, and therefore the keyboard structure can be made having light, thin, short and small characteristics.

3. The frame 11, the press head 12 and the linking device 13 of each key switch module 1 can be assembled and installed at first, and then the circuit board 2 and the membrane 3 are arranged in a stack on the frame 11 of each key switch module 1. According to this mounting arrangement, the circuit board 2 is not necessary to provide the aforesaid slots 23. Further, the modularized installation design of the key switch modules 1 simplifies the fabrication of the keyboard structure.

4. Further, each luminous unit 22 of the circuit board 2 can be formed of an electro luminescent (EL) layer 222 that can be arranged at one or two sides relative to each key switch module 1. Therefore, when the luminous units 22 are electrically connected, the electro luminescent (EL) layer 222 of each luminous unit 22 emits light to illuminate the press head 12 of the associating key switch module 1, and the slots 23 of the circuit board 2 do not interfere with the luminance of the luminous units 22.

In conclusion, the invention provides a keyboard structure with a self-luminous circuit board in which the circuit board 2 is prepared from a flexible light guide material and carrying a circuit layout 211 and set beneath the frame 11 of each key switch module 1 or between the frame 11 and the press head 12 of each key switch module 1, having at least one luminous unit 22 mounted therein for emitting light to illuminate the press heads 12 of the key switch modules 1. Therefore, the dual-function circuit board design reduces the number of component parts required for the keyboard structure, simplifying the manufacturing process of the keyboard structure and lowering the manufacturing cost of the keyboard structure.

Although particular embodiments of the invention have been described in detail for purposes of illustration, various modifications and enhancements may be made without departing from the spirit and scope of the invention. Accordingly, the invention is not to be limited except as by the appended claims.

What the invention claimed is:

1. A keyboard structure, comprising a circuit board, and a plurality of key switch modules installed in said circuit board, each said key switch module comprising a frame and a press head vertically movably supported on said frame for pressing by a user to cause said circuit board to produce a respective electrical signal, wherein said circuit board comprises at least one flexible substrate made of a light guide material, a circuit layout arranged in said at least one flexible substrate, and luminous means mounted in said at least one flexible substrate and electrically connected with said circuit layout for emitting light upwards to illuminate said press heads of said key switch modules.

2. The keyboard structure as claimed in claim 1, wherein said press head of each said key switch module is a key cap or a thin metal sheet.

3. The keyboard structure as claimed in claim 1, wherein said light guide material of said at least one flexible substrate of said circuit board is selected from a material group of polycarbonate (PC), polyethylene terephthalate (PET) and polymethyl methacrylate (PMMA).

4. The keyboard structure as claimed in claim 1, wherein the number of said at least one flexible substrate of said circuit board is 2, and the two flexible substrates are arranged in a stack; said circuit layout and said luminous means of said circuit board are arranged in between said two flexible substrates; said luminous means is comprised of at least one light emitting device.

5. The keyboard structure as claimed in claim 1, wherein the number of said at least one flexible substrate is 1; said circuit layout and said luminous means of said circuit board are arranged on a top side of the single flexible substrate of said circuit board; said circuit board further comprises a resin layer covered on the top side of the single flexible substrate thereof over said circuit layout and said luminous means.

6. The keyboard structure as claimed in claim 1, wherein said luminous means of said circuit board is comprised of an electro luminescent (EL) layer arranged on a top side of said at least one flexible substrate.

7. The keyboard structure as claimed in claim 1, wherein said circuit board comprises light guide means adapted for guiding emitted light from said luminous means toward said press heads of said key switch modules.

8. The keyboard structure as claimed in claim 7, wherein said light guide means of said circuit board comprises at least one of at least one V-shaped protrusion, at least one V-cut and a light guide ink formed on a top side of said at least one flexible substrate.

9. The keyboard structure as claimed in claim 1, further comprising a membrane covered on said circuit board, said membrane comprising a plurality of rubber cones respectively disposed beneath said press heads of said key switch modules and respectively compressible by said press heads of said key switch modules to cause said circuit board to produce a respective electrical signal.

10. The keyboard structure as claimed in claim 9, wherein each said key switch module further comprises a linking device coupled between said frame and said press head of said respective key switch module for guiding vertical displacement of said associating press head relative to said circuit board.

11. The keyboard structure as claimed in claim 10, wherein said frame and said press head of each said key switch module each comprise a plurality of connection portions; said linking device of each said key switch module is coupled between said connection portions of said associating frame and said connection portions of said associating press head; said circuit board and said membrane each comprise a plurality of slots for the passing of said connection portions of said frames of said key switch modules.

12. A keyboard structure, comprising a circuit board, and a plurality of key switch modules installed in said circuit board, each said key switch module comprising a frame and a press head vertically movably supported on said frame for pressing by a user to cause said circuit board to produce a respective electrical signal, wherein said circuit board comprises at least one flexible substrate made of a light guide material and arranged at a bottom side of said frame of each said key switch module, a circuit layout arranged in said at least one flexible substrate, and luminous means mounted in said at least one flexible substrate and electrically connected with said circuit layout for emitting light upwards to illuminate said press heads of said key switch modules.

13. The keyboard structure as claimed in claim 12, wherein said press head of each said key switch module is a key cap or a thin metal sheet.

14. The keyboard structure as claimed in claim 12, wherein said light guide material of said at least one flexible substrate of said circuit board is selected from a material group of polycarbonate (PC), polyethylene terephthalate (PET) and polymethyl methacrylate (PMMA).

15. The keyboard structure as claimed in claim 12, wherein the number of said at least one flexible substrate of said circuit board is 2 and the two flexible substrates are arranged in a stack; said circuit layout and said luminous means of said circuit board are arranged in between said two flexible substrates; said luminous means is comprised of at least one light emitting device.

16. The keyboard structure as claimed in claim 12, wherein the number of said at least one flexible substrate is 1; said circuit layout and said luminous means of said circuit board are arranged on a top side of the single flexible substrate of said circuit board; said circuit board further comprises a resin layer covered on the top side of the single flexible substrate thereof over said circuit layout and said luminous means.

17. The keyboard structure as claimed in claim 12, wherein said luminous means of said circuit board is comprised of an electro luminescent (EL) layer arranged on a top side of said at least one flexible substrate.

18. The keyboard structure as claimed in claim 12, wherein said circuit board comprises light guide means adapted for guiding emitted light from said luminous means toward said press heads of said key switch modules.

19. The keyboard structure as claimed in claim 18, wherein said light guide means of said circuit board comprises at least one of at least one V-shaped protrusion, at least one V-cut and a light guide ink formed on a top side of said at least one flexible substrate.

20. The keyboard structure as claimed in claim 12, further comprising a membrane covered on said circuit board, said membrane comprising a plurality of rubber cones respectively inserted through a respective center opening on said frame of each said key switch module and respectively stopped against said press heads of said key switch modules and respectively compressible by said press heads of said key switch modules to cause said circuit board to produce a respective electrical signal.

21. The keyboard structure as claimed in claim 20, wherein each said key switch module further comprises a linking device coupled between said frame and said press head of said respective key switch module for guiding vertical displacement of said associating press head relative to said circuit board.

22. The keyboard structure as claimed in claim 21, wherein said frame and said press head of each said key switch module each comprise a plurality of connection portions; said linking device of each said key switch module is coupled between said connection portions of said associating frame and said connection portions of said associating press head.

23. The keyboard structure as claimed in claim 20, further comprising a bottom shell, said bottom shell comprising an upright peripheral wall, an accommodation chamber surrounded by said upright peripheral wall and adapted for accommodating said circuit board, said key switch modules and said membrane, and positioning portions protruded from an inner side of said upright peripheral wall and stopped against said frames of said key switch modules at a top side to hold down said membrane and said circuit board inside said accommodation chamber.
